(19) United States
(12) Patent Application Publication
(10) Pub. No.: US 2002/0092471 A1
(43) Pub. Date: Jul. 18, 2002

(54) Semiconductor deposition apparatus and shower head

(75) Inventors: Sang-Bom Kang, Seoul (KR); Chang-Won Lee, Kyungki-do (KR); Gil-Heyun Choi, Kyungki-do (KR); Seong-Geon Park, Kyungki-do (KR)

Correspondence Address: MARGER JOHNSON & McCOLLOM, P.C., 1030 S. W. Morrison Street, Portland, OR, 97205, US

(73) Assignee: Samsung Electronics Co., Ltd., Suwon-city (KR)

(21) Appl. No.: 10/052,703

(22) Filed: Jan. 16, 2002

(30) Foreign Application Priority Data
Jan. 17, 2001 (KR) 01-2638

(51) Int. Cl. C23C 16/00; C23F 1/00

(52) U.S. Cl. 118/715; 118/722; 156/345.33

(57) ABSTRACT

A deposition apparatus and shower head are provided. The shower head preferably includes a plurality of plates having gas paths formed therein. A cooling system is arranged in a lower plate of the shower head and includes a plurality of independent inner cooling lines configured to connect coolant inlets to coolant outlets. A separating device is also disclosed herein. The separating device preferably separates a heater stage from a chamber body to thereby separate a processing chamber of the deposition apparatus from a dead volume located beneath the heater stage. Various other improvements are also provided to improve the efficiency of a deposition process, and, in particular, an ALD process.

This application claims priority from Korean Patent Application No. 2001-2638, filed Jan. 17, 2001, the contents of which are hereby incorporated herein by reference in their entirety.

### BACKGROUND OF THE INVENTION

1. Field of the Invention

The present invention relates to an apparatus for manufacturing semiconductor devices, and more particularly, to an apparatus having a shower head for forming a thin film on a semiconductor substrate.

2. Description of Related Art

An atomic layer deposition (ALD) process has been introduced as a method of depositing a thin film on a wafer in the manufacturing of semiconductor devices. During the ALD process, purging and pumping of reactants is performed repetitively within a short time. Both purging time and pumping time increase in proportion to an increase in the volume of a process chamber. Accordingly, the volume of processing space within the process chamber of an ALD apparatus should be minimized. Minimizing the volume of the process chamber reduces deposition time by minimizing purging time and pumping time. Unfortunately, however, ALD utlizes a high temperature process, in which the temperature of a wafer is maintained substantially above 500° C. The high temperature makes it difficult to reduce the internal processing space.

In particular, the temperature of the surface of a shower head in the ALD apparatus can rise due to radiant heat emitted from the surface of a heater, on which the wafer is placed. If the temperature of the shower head rises above a predetermined temperature, the shower head can corrode. In addition, as the temperature of the shower head increases, unwanted particles can be produced if a reaction gas, introduced into the process chamber through the shower head, reacts on the surface of the shower head. Furthermore, where the shower head is formed of numerous plates, O-rings introduced to vacuum seal the plates can be deformed as the temperature of the shower head increases.

To overcome these problems, it is desirable to prevent excessive increase of the temperature of the shower head. In one conventional method, a predetermined distance separates the heater and the shower head to reduce heat transfer therebetween. This separation between the heater and the shower head, however, increases the volume of the chamber. Also, in the ALD process, at least two kinds of reaction gases are repeatedly provided to the wafer from the shower head during a short period of time to form the thin film. As the separation distance between the heater and the shower head increases, it therefore becomes more difficult to perform the ALD process.

It is therefore desirable to prevent the temperature of the shower head from increasing while minimizing the separation distance between the shower head and the heater. In some deposition systems, a cooling system has been installed in the shower head to prevent an increase in the temperature of the shower head. Such cooling systems are described, for example, in U.S. Pat. No. 5,968,276 (entitled “Heat Exchange Passage Connection”, issued to Lawrence Lei, et al, on Oct. 19, 1999) and U.S. Pat. No. 5,595,606 (entitled “Shower Head and Film Forming Apparatus Using the Same”, issued to Fujikawa, et al, on Jan. 21, 1997). Despite the improvements offered thereby, more effective methods of preventing an increase in the temperature of the shower head are desired.

To minimize the volume of the process chamber, it is also desirable to minimize the dead volume in the chamber. Dead volume results, for instance, from separation between the heater and the body of the process chamber. The temperature of the chamber body, such as the walls of the chamber, will increase due to the operation of the high temperature heater. Because the chamber body is mainly formed of a metal, such as aluminum, if the chamber body is in contact with the heater, or close to it, its temperature will increase as a result of conductive and/or radiant heat transfer from the heater. Problems such as thermal shock or the generation of contaminant particles can occur as the body temperature increases. In one method, to reduce heat transfer from the heater to the chamber body, the heater is separated from the chamber body.

According to this method, the chamber body and heater are separated by providing separating spaces between the heater and the bottom of the chamber. Unfortunately, this separation creates extra space beneath the heater and the volume of the chamber inevitably increases. Accordingly, although this method is acceptable for use in a general chemical mechanical deposition (CVD) method, it is undesirable for the ALD process because a vacuum must be maintained in the entire process chamber. The dead volume resulting from this separation space increases the difficulty of the ALD process.

In conventional deposition systems (such as the ALD apparatus described above) that employ high temperature heaters, it has been difficult to avoid dead volume. Dead volume within the processing chamber of the apparatus increases the volume of the process chamber and therefore increases purging time. As a result, the time and complexity of the ALD process increases in proportion to the amount of dead volume.

### SUMMARY OF THE INVENTION

The present invention provides a shower head that evenly distributes a reaction gas to a wafer in a process chamber.

The present invention also provides an apparatus capable of keeping the shower head cool while reducing the distance between the shower head and a high temperature heater to reduce the inner volume of a process chamber and thereby reduce purging and pumping time, and the time required for forming the thin film.

In addition, the present invention provides an apparatus that minimizes dead volume beneath a high temperature heater to reduce the inner volume of a process chamber in which the shower head is introduced, thereby reducing purging and pumping time, and the time required for forming a thin film.

According to a first preferred aspect of this invention, a shower head is arranged to evenly supply a reaction gas to a wafer located in a process chamber. The shower head includes a plurality of plates having gas paths configured therein to supply the reaction gas to the wafer. The shower head is also provided with a cooling system. The cooling system includes a plurality of coolant inlets and coolant outlets formed in the shower head plate that is located nearest to the wafer. Independent inner cooling lines connect each of the coolant inlets to a corresponding coolant outlet.

An apparatus for forming a thin film on a wafer is also provided according to another preferred aspect of this invention. The apparatus includes a process chamber. A heater stage is installed in a lower portion of the process chamber to support a wafer and heat the wafer to a high temperature. A shower head is installed above the heater stage to supply a reaction gas to the wafer. A separating device is introduced between the bottom of the process chamber and the heater stage, in a space separating the heater stage from a process chamber, to reduce a volume of actual processing space. The separating device is preferably formed of a heat-resistant material, such as a ceramic, and can be attached to the bottom of the heater stage.

According to yet another aspect of this invention, an apparatus for forming a thin film includes a heater stage installed in a lower portion of a process chamber. The heater stage supports and heats a wafer to a high temperature. A plurality of plates are installed in a shower head above the heater stage. Gas paths are formed in the plates to supply a reaction gas to the wafer. A cooling system is provided in a plate closest to the wafer. The cooling system includes a plurality of coolant inlets and coolant outlets as well as a plurality of independent inner cooling lines that connect each of the coolant inlets to a corresponding coolant outlet. A separating device is also provided in the space between the bottom of the process chamber and the heater stage to fill at least a portion of the space separating the heater stage from the process chamber body. The separating device thereby reduces the volume of the processing space.

According to the foregoing aspects of the present invention, the lowest plate of the shower head, located opposite the high temperature heater stage, can be cooled effectively.

The volume of the chamber can therefore be reduced. Dead volume can be reduced by 10 providing a separating device to occupy at least a portion of the dead volume. Using the various aspects of this invention, therefore, the time required for performing a process, such as ALD, that requires repetitive purging and pumping can be shortened.

### BRIEF DESCRIPTION OF THE DRAWINGS

The forgoing objects and advantages of the present invention will become more apparent through the following detailed description of preferred embodiments, made with reference to the attached drawings, wherein like reference numerals represent like elements, and in which:

FIG. 1 is a cross-sectional side view schematically illustrating an apparatus for forming a thin film according to a preferred embodiment of the present invention;

FIGS. 2 through 4 are plan views schematically illustrating various embodiments of a cooling system arranged in a lower plate of a shower head according to another aspect of the present invention; and

FIGS. 5 and 6 are a perspective view and cross-sectional side view, respectively, schematically illustrating a separating device used to reduce dead volume in a film deposition apparatus according to yet another aspect of the present invention.

### DETAILED DESCRIPTION OF PREFERRED EMBODIMENTS

The present invention will now be described more fully in terms of preferred embodiments thereof. It should be recognized, however, that these embodiments are exemplary only and that this invention can be embodied in many different forms. It should therefore not be construed as limited to the express embodiments set forth herein. It should also be noted that the accompanying drawings are not to scale. The sizes and thicknesses of layers and regions are exaggerated for ease of reference.

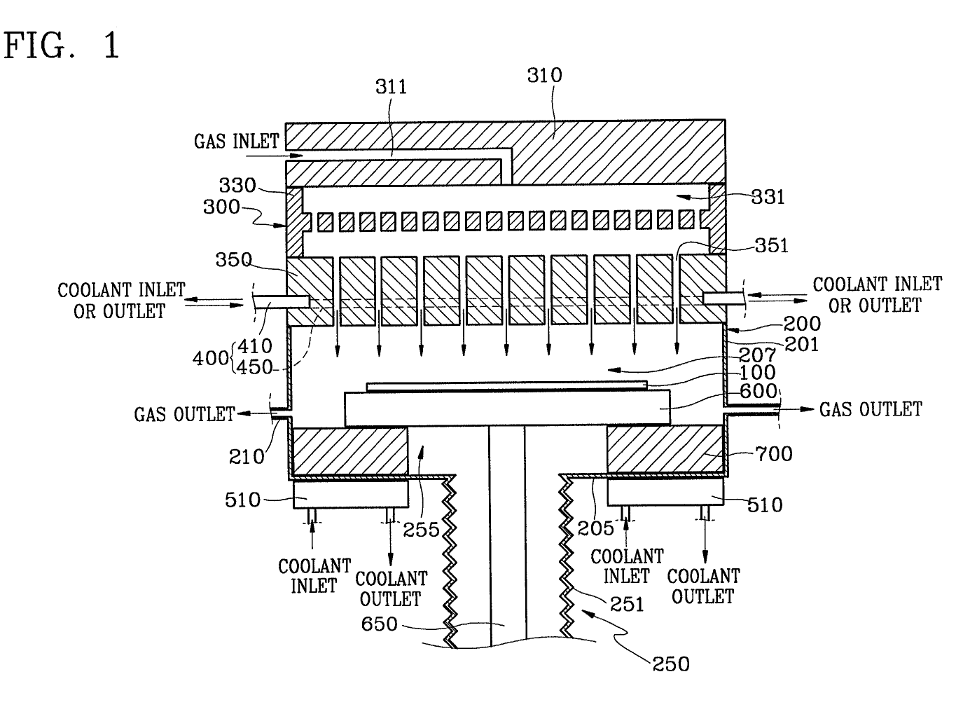

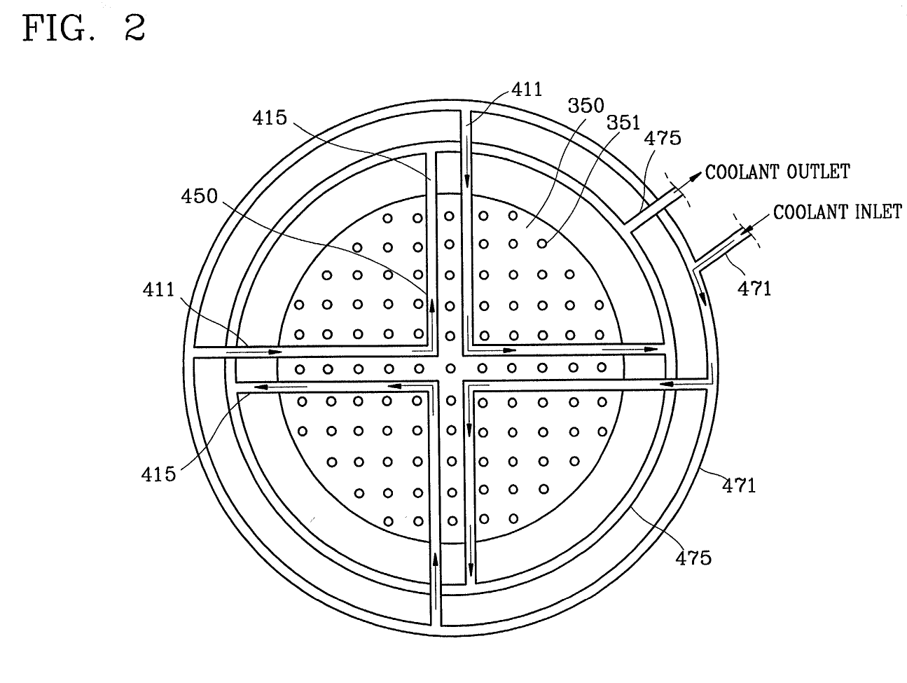

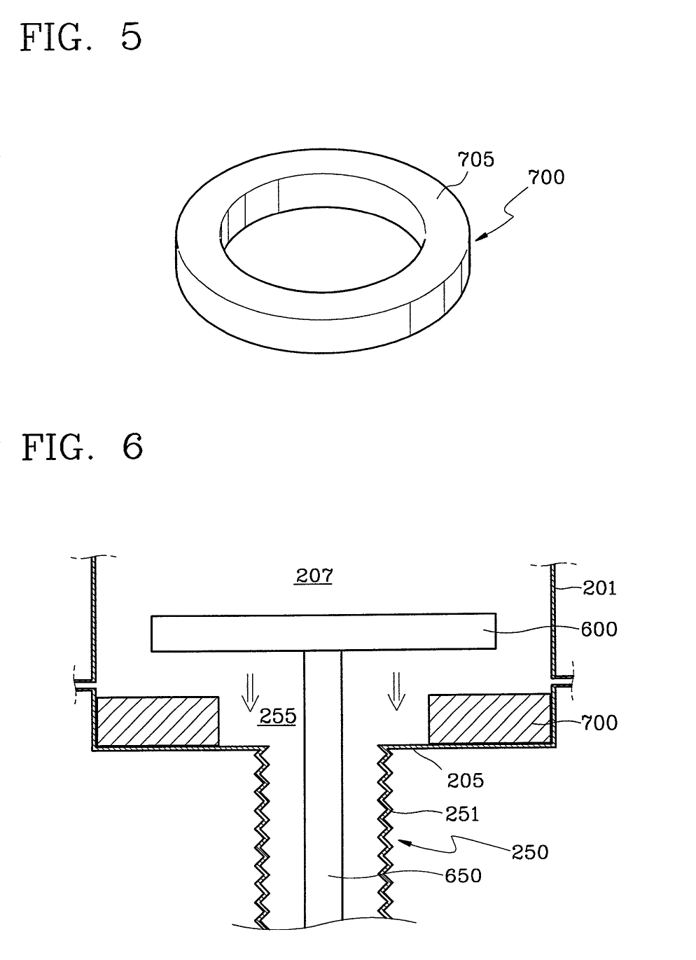

As noted previously, FIG. 1 schematically illustrates a film depositing apparatus having a shower head, constructed according to a preferred embodiment of the present invention. FIGS. 2 through 4 illustrate preferred embodiments of a cooling system introduced in a lower plate of the shower head of FIG. 1. FIGS. 5 and 6 schematically illustrate a preferred embodiment of a separating device used in the apparatus of FIG. 1.

Referring to FIG. 1, an apparatus for forming a thin film according to a preferred embodiment of the present invention includes a process chamber 200. The process chamber 200 provides a reactor in which a reaction is performed to form the thin film on a wafer 100. A shower head 300 is arranged in an upper portion of the process chamber 200. A heater stage 600 is arranged in a lower portion of the process chamber 200, below the shower head 300. The heater stage 600 supports and heats the wafer 100. Electrodes (not shown) are built into the heater stage 600 to apply a bias to the wafer 100. The heater stage 600 heats the wafer 100 to a high temperature of around 500° C. or higher during an atomic layer deposition (ALD) process. The heater stage 600 employs a high temperature heater comprising a ceramic material such as aluminum nitride (A1N).

The shower head 300, introduced over the heater stage 600, provides a reaction gas to the wafer 100. The reaction gas preferably includes two or more different reaction gases for the ALD method, and each of the reaction gases is provided into the process chamber 200 through an independent supply path.

Specifically, the shower head 300 has a plurality of reaction gas supply paths 311, 331, 351 within the shower head 300, to evenly supply the reaction gas to the surface of the wafer 100. The supply paths 311, 331, 351 can provide at least two independent paths, which are necessary for the ADL process. Although only one of the two or more independent paths is shown in FIG. 1, the other path (not shown) is formed in a manner similar to that of the described path. Each of the paths preferably branches out into a plurality of paths within the shower head 300, so that the reaction gas is evenly supplied to the wafer 100.

More specifically, the shower head 300 is formed having a plurality of plates 310, 330, 350 that provide the branching paths 311, 331, 351. For example, a first path 311 is formed in a first plate 310, located in the uppermost (i.e., top) part of the shower head 300. The first path 311 provides an inlet for the reaction gas. A second path 331 is formed in a second plate 330. The second plate is adhered to a lower portion of the first plate 310. The second path 331 widely distributes the reaction gas. The lowest (third) plate 350 is adhered to a lower portion of the second plate 330. The third plate 350 has a third path 351 arranged therein to evenly distribute the reaction gas to the chamber 200.

The shower head 300, formed from the combination of the three plates 310, 330, 350, evenly distributes reaction gas to the wafer 100. Gaps between the plurality of plates 310, 330, 350 are sealed with a sealing member, such as an O-ring, to prevent the reaction gas that flows through the paths 311, 331, 351 from leaking. If the high temperature heater stage 600 causes the temperature of the shower head 300 to increase, the sealing member may become deformed, thus causing vacuum leakage of the chamber 200. To prevent this, a cooling system 400 can be introduced into the shower head 300.

A lower side of the shower head 300 is arranged directly above the high temperature heater stage 600. Accordingly, a lower side of the third plate 350 is directly heated by the radiant heat of the heater stage 600. In a preferred embodiment of the present invention, therefore, the cooling system 400 is installed directly in the third plate 350. By installing the cooling system directly into the third plate 350, the heated portion of the shower head 300 can be cooled more effectively and efficiently.

Still referring to FIG. 1, the cooling system 400 preferably includes a primary coolant inlet 410 connected to a primary coolant outlet 410 through a cooling passage. The cooling passage may include one or more inner cooling lines 450. The inner cooling lines 450 are preferably formed within the third plate 350. The primary coolant inlet and outlet 410 are connected to the cooling lines 450 in the third plate 350. For example, the coolant inlet and outlet 410 can be arranged on an edge of the third plate 350.

Various embodiments of the cooling system 400 will now be described more fully with reference to FIGS. 2 through 4. Referring to FIG. 2, a primary cooling inlet 410a may supply coolant to a plurality of coolant inlets 411. The coolant travels through the inner cooling lines 450 in the third plate 350 to a plurality of coolant outlets 415. In this particular embodiment, for example, four coolant inlets 411 are arranged symmetrically along the edge of the third plate 350. Four coolant outlets 415 are also arranged symmetrically along the edge of the third plate 350. Four separate, independent inner cooling lines 450 are arranged within the third plate 350 to connect the coolant inlets 411 to the coolant outlets 415.

More specifically, a first outer cooling line 471 supplies coolant to the inner cooling lines 450 through the coolant inlets 411. The inner cooling lines 450 circulate the coolant and output the circulated coolant via a second outer cooling line 475, which is connected to the cooling outlets 415. The first outer cooling line 471 receives coolant from the primary coolant inlet 410a and provides the coolant to each of the coolant inlets 411. The second outer cooling line 475 acts as a passage for discharging the circulated coolant from each of the coolant outlets 415 through a primary coolant outlet 410b. The first and second outer cooling lines 471, 475 can, for example, wrap around the circumference of the third plate 350. The first and second outer cooling lines 471, 475 can also be exposed to an external environment. In this case, the first and second outer cooling lines 471, 475 are preferably protected using an adiabatic material.

The inner cooling lines 450 are preferably distributed evenly within the third plate 350 to uniformly and effectively cool the third plate 350. The four coolant inlets 411, for example, can be installed 90 degrees apart from each other along the edge of the third plate 350. Similarly, the coolant outlets 415 can be installed at 90 degree intervals along the edge of the third plate 350. The coolant outlets 415 may be arranged in proximity with the coolant inlets 411 or they may be arranged at a predetermined angular distance from the coolant inlets 411. The inner cooling lines 450, which connect the coolant outlets 415 to the coolant inlets 411, can be arranged in a path that forms a predetermined angle (e.g., about 90 degrees) having a vertex near the center of the third plate 350. The inner cooling lines 450 are preferably arranged so as not to block the through holes that provide the reaction gas supply paths 351.

As described above, the cooling system 400 can effectively cool the third plate 350 of the shower head 300 using the plurality of coolant inlets 411, the plurality of coolant outlets 415, and the plurality of independent inner cooling lines 450. An undesirable temperature gradient within the third plate 350 can be prevented by symmetrically arranging the plurality of coolant inlets 411. Installing more than four coolant inlets can further reduce variations in the temperature across the third plate 350.

According to this embodiment, unlike the apparatus disclosed in U.S. Pat. No. 5,595,606, the coolant inlets 411 are directly connected to the edge of the third plate 350 to prevent contamination of the chamber 200 as a result of coolant leakage. Also, a coolant passage that passes through the first plate 310, the second plate 330, and the third plate 350 is not needed in the shower head 300. Because the coolant inlets 411 and outlets 415 are only arranged on the edge of the third plate 350, the cooling system is easily added to the shower head 300, thereby simplifying the structure of the shower head 300.

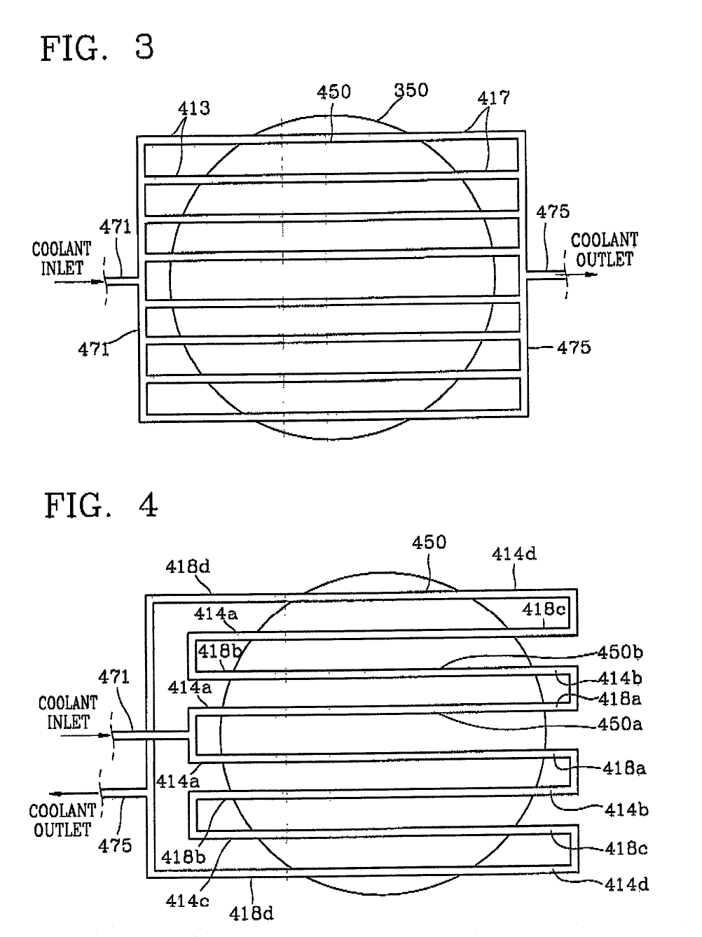

FIG. 3 illustrates another embodiment of the cooling system 400 installed in the third plate 350 of the apparatus of FIG. 1. Referring to FIG. 3, a plurality of coolant inlets 413 are installed along one side of the third plate 350 and a plurality of coolant outlets 417 are installed along the other side of the third plate 350 directly opposite the coolant inlets 413. The coolant inlets 413 are connected to a first outer cooling line 471, and the coolant outlets 417 are connected to a second outer cooling line 475. The independent inner cooling lines 450, which connect the coolant inlets 413 to the coolant outlets 417, pass through the third plate 350. The plurality of inner cooling lines 450 are arranged parallel to each other. In other words, the first outer cooling line 471 branches into a plurality of inner cooling lines 450, which, in turn, collapse back into the second outer cooling line 475 to provide the substantially entire cooling passage of this embodiment. In this manner, the third plate 350 can be evenly cooled and temperature variations therein can be minimized.

FIG. 4 illustrates still another possible embodiment of the cooling system 400, which can be installed in the third plate 350 of the apparatus of FIG. 1. Referring now to FIG. 4, a plurality of coolant inlets 414 and a plurality of coolant outlets 418 are arranged alternately on opposite sides of the third plate 350. First coolant inlets 414a are located on a first side of the third plate 350. The first coolant inlets 414a are connected to first coolant outlets 418a through first inner cooling lines 450a. The first coolant outlets 418a are located on a second, opposite side of the third plate 350. The first coolant outlets 418a are connected to second coolant inlets 414b, which are located adjacent to the first coolant outlets 418a on the second side of the third plate 350. The second coolant outlets 418b are connected to second coolant inlets 414b through second inner cooling lines 450b. The first coolant inlets 414a are located next to the second coolant outlets 418b on the first side of the third plate 350. Accordingly, the coolant outlets 418 and coolant inlets 414 are alternately located on opposite sides of the third plate 350, with the inner independent cooling lines 450 installed parallel to each other.

Coolant enters the cooling passage through a primary cooling inlet 410a and travels into the first coolant inlets 414a, located on the first side of the third plate 350, from a first outer cooling line 471. Coolant entering the first coolant inlets 414a flows through the first cooling lines 450a to the first coolant outlets 418a, located on the second side of the third plate, arranged opposite the first side. Coolant from the first coolant outlets 418a then flows into a second coolant inlet 414b, which is also located on the second side of the third plate 350. The coolant then flows back through the third plate 350 through second cooling lines 450b into second coolant outlets 418b, located on the first side of the third plate 350. In this way, coolant proceeds back and forth through the third plate 350 until it reaches a second outer cooling line 475, which then outputs the coolant through a primary coolant outlet 410b. The coolant thereby flows through neighboring inner cooling lines 450 in opposite directions. Using the forgoing embodiments, the third plate 350 can be evenly cooled and temperature variations within the third plate 350 can be minimized.

In summary, referring to FIGS. 1 through 4, the shower head 300 according to various preferred embodiments of the present invention includes a cooling system 400 that comprises a plurality of coolant inlets 411, 413, 414 and a plurality of coolant outlets 415, 417, 418 installed in the third plate 350. The cooling system prevents temperature variations by evenly cooling the shower head 300. Effectively cooling the shower head 300 allows a separation distance between the shower head 300 and the heater stage 600 to be reduced, thus improving system performance. For example, according to preferred embodiments of this invention, the separation distance between the heater stage 600 and the shower head 300 can be reduced to less than approximately 3 cm. The height of the side walls 201 of the process chamber 200 can therefore be reduced, thereby decreasing the inner volume of the process chamber 200. The repetitive action of supplying reaction gas, and the accompanying repetitive purging and pumping processes in the ALD process can be performed in a reduced amount of time. The time for completing the entire ALD process can thereby be reduced.

The processing time of a deposition process, such as the ALD process, for forming a thin film on a semiconductor wafer can be further decreased by reducing the dead volume.

Referring again to FIG. 1, dead volume is mainly a result of the separation distance between the high temperature heater stage 600 and the bottom 205 of the chamber 200. A volume inside a shaft introduction portion 250, which provides a passage for a shaft 650 to raise and lower the heater stage 600, may also contribute to the dead volume. Dead volume increases purging and pumping time. To reduce dead volume in a preferred embodiment of the present invention, a separating device 700 is supplied to the deposition apparatus.

The separating device 700 is arranged between the process chamber 200 and the heater stage 600. The separating device 700 separates an inner space 207 of the process chamber 200, which contains the wafer 100, from a space 255 located beneath the heater stage 600. The dead volume is thereby substantially eliminated and the volume of the process space is thereby reduced.

Referring to FIGS. 1, 5, and 6, the separating device 700 is preferably formed having a rim-like shape and is located along a bottom 205 of the process chamber 200, close to the bottom of the heater stage 600. The separating device 700 is preferably formed having a uniform thickness to evenly separate the heater stage 600 from the bottom 205 of the process chamber 200. The heater stage 600 and the bottom 205 of the process chamber 200, can, for example, be separated by a distance of about 2-10 cm, depending on the thickness of the separating device 700. The separation between the heater stage 600 and the chamber bottom 205 helps reduce the amount of heat transfer from the heater stage 600 to the chamber 200. In addition, the separating device 700 is preferably formed of a heat-resistant or adiabatic material to prevent the separating device 700 from transmitting heat from the heater stage 600 to the bottom 205 of the chamber 200. The separating device 700 is most preferably formed of a ceramic material.

The separating device 700 is preferably arranged such that a bottom surface is located in proximity with the chamber bottom 205. A top surface 705 of the separating device 700 is preferably flat to permit it to adhere closely to the bottom of the heater stage 600. The top surface 705 of the separating device 700 may also be surface-treated with a smooth coating to more effectively seal off the dead space 255. When the heater stage 600 adheres closely to the separating device 700, the inner space 207 of the chamber 200, in which the deposition process is performed, is effectively separated from the dead space 255. The inner volume of the process chamber 200 is thereby reduced, allowing purging time and pumping time in the deposition process to be reduced.

A wall 251 of the shaft introduction portion 250 is preferably designed to provide wall flexibility. A bellows-type wall 251, for example, can be used for the shaft introduction portion 250. With this configuration, the height of the shaft introduction portion 250 can vary with movement of the shaft 650. A power cable, for supplying power to the heater stage 600, can be built into the shaft 650. A gas inlet 210 and a gas outlet 210, for pumping gas into and purging gas from the process chamber 200, are preferably arranged through a side wall 201 of the chamber 200 near the separating means 700.

To more effectively prevent the bottom 205 of the process chamber 200 from being heated by the heater stage 600, a chamber cooling means 510 can be provided to cool the bottom 205 of the process chamber 200. According to this aspect of the invention, the chamber cooling means 510 circulates a coolant in proximity with the chamber bottom 205 to prevent the bottom 205 of the chamber 200 from becoming overheated.

According to various aspects and embodiments of the present invention, a cooling system having a simple structure can be installed in a lower plate of a shower head of a deposition apparatus. The portion of the shower head that is exposed to radiant heat from the heater stage can be effectively cooled thereby. Temperature variations within the lower plate of the shower head can also be minimized, and the structure of the shower head can be simplified using the principles described herein.

As a result, heating of the shower head by the heater stage can be substantially prevented. By preventing excessive heating of the shower head, corrosion of the shower head and deformation of shower head components can also be prevented. In addition, by more effectively cooling the shower head, the separation distance between the shower head and the high temperature heater stage can be reduced, thereby reducing the volume of the process chamber. As the volume of the process chamber decreases, the time needed for performing processes, such as the ALD process, which require repetitive purging and pumping, is also reduced. A ceramic separating device can further be provided between the heater stage and the bottom of the chamber to separate dead space beneath the heater stage from the processing space in the chamber. This reduces dead volume in the processing chamber and therefore also reduces the processing time of the deposition process.

Although this invention has been shown and described with reference to several preferred aspects and embodiments thereof, it will be understood by those skilled in the art that various changes in form and details may be made thereto without departing from the spirit and scope of the invention as defined by the appended claims.

What is claimed is:

1. A shower head for supplying a reaction gas to a wafer in a process chamber, the shower head comprising:
a plurality of plates comprising gas paths for supplying a reaction gas to a wafer; and
a cooling system comprising a plurality of coolant inlets and a plurality of coolant outlets formed in a lower one of the plurality of plates, and further comprising a plurality of inner cooling lines configured to connect each of the plurality of coolant inlets to one of the plurality of coolant outlets.

2. A shower head according to claim 1, wherein the plurality of coolant inlets and the plurality of coolant outlets are formed on a side of the lower plate.

3. A shower head according to claim 1, wherein at least four coolant inlets, at least four coolant outlets, and at least four inner cooling lines are formed.

4. A shower head according to claim 1, wherein the plurality of coolant inlets are formed on a first side of the lower plate, the plurality of coolant outlets are formed on a second side of the lower plate, and the plurality of inner cooling lines are formed parallel to each other.

5. A shower head according to claim 1, wherein a first coolant inlet is connected to a first coolant outlet by a first inner cooling line, wherein a second coolant outlet is connected to a second coolant inlet by a second inner cooling line, and wherein the second coolant outlet is located adjacent to the first coolant inlet on a first side of the lower plate.

6. A shower head according to claim 1, wherein a first coolant outlet is connected to a first coolant inlet by a first inner cooling line, and wherein the first coolant outlet is positioned approximately 90 degrees from a position of the first coolant inlet along an circumferential edge of the lower plate.

7. A shower head according to claim 6, wherein a second coolant inlet is located adjacent to the first coolant outlet, wherein the second coolant outlet is connected to a second coolant inlet by a second inner cooling line, and wherein the second coolant outlet is located approximately 90 degrees from a position of the second coolant inlet along the edge of the lower plate, and wherein the second coolant outlet is located approximately 180 degrees from the first coolant inlet along the edge of the lower plate.

8. A shower head according to claim 1, further comprising:
a first outer cooling line arranged outside the lower plate to connect the plurality of coolant inlets; and
a second outer cooling line arranged outside the lower plate to connect the plurality of coolant outlets.

9. An apparatus for forming a thin film, said apparatus comprising:
a process chamber;
a heater stage located in a lower portion of the process chamber, said heater stage configured to support a wafer and to heat the wafer to a high temperature;
a shower head located in an upper portion of the process chamber, said shower head configured to supply a reaction gas to the wafer; and
a separating device arranged between the process chamber and the heater stage, said separating device configured to separate the heater stage from the process chamber and to reduce a volume of processing space within the process chamber.

10. An apparatus according to claim 9, wherein the high temperature is about 500° C.

11. An apparatus according to claim 9, wherein the separating device is located in a lower portion of the process chamber and contacts a bottom of the heater stage.

12. An apparatus according to claim 9, wherein the separating device is configured to separate the heater stage and the process chamber by a uniform distance.

13. An apparatus according to claim 12, wherein the heater stage and the process chamber are separated by about 2-10 cm.

14. An apparatus according to claim 9, wherein the separating device is formed of a heat-resistant material.

15. An apparatus according to claim 14, wherein the heat-resistant material is a ceramic material.

16. An apparatus according to claim 9, wherein the separating device is rimshaped and is configured to closely adhere to the bottom of the heater stage.

17. An apparatus according to claim 9, further comprising:
a shaft installed beneath the heater stage and configured to raise and lower the heater stage; and
a shaft introduction portion configured to introduce the shaft at the bottom of the process chamber.

18. An apparatus according to claim 17, wherein shaft introduction portion is formed as a flexible bellows and has a length that varies as the shaft is raised and lowered.

19. An apparatus according to claim 9, further comprising a process chamber cooling system configured to cool a bottom surface of the process chamber whereon the separating device is located.

20. An apparatus for forming a thin film, said apparatus comprising:
a process chamber;
a heater stage arranged in a lower portion of the process chamber and configured to support a wafer and to heat the wafer to a high temperature;
a shower head disposed in an upper portion of the process chamber and configured to supply a reaction gas to the wafer, said shower head comprising a plurality of plates having a plurality of gas paths formed therein and a shower head cooling system arranged in a lower plate;
said cooling system comprising a plurality of coolant inlets, a plurality of coolant outlets, and a plurality of independent inner cooling lines for connecting each of the coolant inlets to one of the coolant outlets; and
a separating device arranged between the process chamber and the heater stage to separate a space beneath the heater stage from a process chamber space containing the wafer to reduce a process volume of the process chamber.

21. An apparatus according to claim 20, wherein the plurality of coolant inlets and the plurality of coolant outlets are formed along an edge of the lower plate.

22. An apparatus according to claim 20, wherein at least four coolant inlets, at least four coolant outlets, and at least four inner cooling lines are formed.

23. An apparatus according to claim 20, wherein the plurality of coolant inlets are formed on one side of the lower plate, the plurality of coolant outlets are formed on an opposite side of the lower plate, and the plurality of inner cooling lines are formed parallel to each other.

24. An apparatus according to claim 20, wherein a first coolant outlet is connected to a first coolant inlet by a first inner cooling line, wherein a second coolant inlet is connected to a second coolant outlet by a second inner cooling line, wherein the second coolant outlet is arranged adjacent to the first coolant inlet on a first side of the lower plate, wherein the first coolant outlet is located adjacent to the second coolant inlet on a second side of the lower plate, and wherein the second side of the lower plate is opposite the first side.

25. An apparatus according to claim 20, wherein a first coolant outlet is connected to a first coolant inlet by a first inner cooling line, wherein the first inner cooling line has a path that forms an approximately 90 degree angle, said angle having a vertex located at approximately the center of the lower plate.

26. An apparatus according to claim 25, wherein a second coolant inlet is located adjacent to the first coolant outlet, and wherein a second coolant outlet is connected to the second coolant inlet by a second inner cooling line, and wherein the second outlet is located approximately 90 degrees from the second coolant inlet along a circumferential edge of the lower plate, and wherein the second outlet is located approximately 180 degrees from the first coolant inlet along the circumferential edge of the lower plate.

27. An apparatus according to claim 20, further comprising:
a first outer cooling line located outside the lower plate and configured to connect the plurality of coolant inlets; and
a second outer cooling line located outside the lower plate and configured to connect the plurality of coolant outlets.

28. An apparatus according to claim 20, wherein the high temperature is about 500° C.

29. An apparatus according to claim 20, wherein the separating device is arranged in proximity to a bottom of the heater stage in a lower portion of the process chamber.

30. An apparatus according to claim 20, wherein the heater stage and the process chamber are separated by a substantially uniform distance using the separating device.

31. An apparatus according to claim 30, wherein the heater stage and the process chamber are separated by about 2-10 cm.

32. An apparatus according to claim 20, wherein the separating device is formed of a heat-resistant material.

33. An apparatus according to claim 32, wherein the heat-resistant material is a ceramic material.

34. An apparatus according to claim 20, wherein the separating device is rim shaped and is configured to closely adhere to a bottom of the heater stage.

35. An apparatus according to claim 20, further comprising:
a shaft configured to raise and lower the heater stage, said shaft arranged beneath the heater stage; and
a shaft introduction portion configured to contain the shaft at the bottom of the process chamber.

36. An apparatus according to claim 35, wherein the shaft introduction portion comprises a flexible bellows wall having a variable length depending on the raising and lowering of the shaft.

37. An apparatus according to claim 20, further comprising a process chamber cooling system arranged in thermal communication with a lower portion of the process chamber, said lower portion of the process chamber supporting the separating device.

38. A method for reducing processing time in a deposition process, said method comprising:
reducing a separation distance between a shower head and a heater stage;
reducing a dead volume in a process chamber; and
thereby reducing a volume of the process chamber and increasing the speed of a deposition process requiring repeated pumping and purging of a reaction gas.

39. A method according to claim 38 wherein reducing a separation distance between a shower head and a heater stage comprises supplying a cooling solution to a lower plate of a plurality of plates in the shower head.

40. A method according to claim 38 wherein reducing the dead volume in the process chamber comprises separating a processing space from a dead volume in the process chamber by providing a separating device between a bottom of the process chamber and a bottom of the heater stage.
